(19) United States
(12) Patent Application Publication
(10) Pub. No.: US 2004/0229391 A1
(43) Pub. Date: Nov. 18, 2004

(54) LED lamp manufacturing process

(76) Inventors: Kazuyuki Ohya, Katsushika-ku (JP); Norio Sayama, Chiyoda-ku (JP); Hisashi Ohwada, Katsushika-ku (JP)

Correspondence Address: WENDEROTH, LIND & PONACK, L.L.P., 2033 K STREET N. W., SUITE 800, WASHINGTON, DC, 20006-1021, US

(21) Appl. No.: 10/830,312

(22) Filed: Apr. 23, 2004

(30) Foreign Application Priority Data
Apr. 25, 2003 (JP) 2003-121115
Jul. 11, 2003 (JP) 2003-273157

(51) Int. Cl. H01L 21/00

(52) U.S. Cl. 438/26

(57) ABSTRACT

An LED lamp manufacturing process comprising manufacturing a multi-layer printed wiring board having a large number of LED lamp portions, each comprising a depressed portion whose side wall reflects light and has a mounted LED chip sealing resin container function and whose inner bottom has an LED chip mounting pattern, and a terminal pattern which is made conductive with the LED chip mounting pattern and formed on the outer under surface or outer side surface of the depressed portion, mounting predetermined LED chips on the LED chip mounting patterns, sealing the depressed portions with a resin and cutting the board into individual LED lamps, wherein the process comprises:

a) preparing a plated through hole printed wiring board (P) having LED chip mounting patterns and terminal patterns formed thereon;

b) preparing a through hole formed board (H) having through holes which correspond to the depressed portions and if necessary, have a treated wall to increase reflectance; and

c) aligning the through hole formed board (H) with the above plated through hole printed wiring board (P) and bonding them together.

According to the present invention, an LED lamp having a greatly increased LED chip mounting space can be manufactured and its assembly work can be simplified. Therefore, the manufacturing process of the present invention has a great industrial value.

### BACKGROUND OF THE INVENTION

1. Field of the Invention

The present invention relates to a novel LED lamp manufacturing process, specifically an LED lamp manufacturing process which allows use of a substrate having a high thermal conductivity while high productivity is ensured, more specifically an LED lamp manufacturing process which can eliminate the restrictions on mounting operation of the narrow space of an LED chip mounting portion.

2. Description of the Prior Art

In a conventional surface mounting LED lamp manufacturing process, for example, a copper-clad glass epoxy laminated board containing a large amount of a white inorganic filler is used to manufacture a three-layer board comprising an LED chip mounting pattern interlayer, the mounting portion is exposed by counterboring, LED chips are mounted in that mounting portion and suitably sealed with a resin, and the resulting board is cut into individual LED lamps. The reason why a large amount of a white inorganic filler is used is that heat resistance is improved by the inorganic filler to facilitate supersonic bonding and light reflectance is improved by the white filler to enhance brightness.

There is proposed another surface mounting LED lamp comprising a ceramic sintered material, especially an alumina sintered material in place of a resin substrate. Supersonic bondability which is one of the problems of a conventional resin substrate is improved by using the ceramic.

Remarkable progress has been made in the LED field, as symbolized by the invention of a blue LED and progress in its commercialization. Accomplish of a small-sized, multi-color or high-density LED lamp, and accomplishing simultaneously therewith is now in demand, and use of the LED lamp as an auto head light is desired.

Although an LED is a light emitting device having high efficiency, an LED lamp having the above characteristic features has a high heating density and value, generates a large quantity of heat and therefore cannot be used in conjunction with a conventional resin substrate.

In order to meet the above size, density and color requirements, LED chips must be mounted in an extremely narrow area in the conventional LED lamp manufacturing process in which a multi-layer printed wiring board having an LED chip mounting portion is used, and the development of an assembly device for manufacturing this LED lamp is difficult.

As means of solving a heat generation problem, use of ceramics having high heat conductivity is now under study. However, it is difficult to meet the size and density requirements because a plurality of LED chips are mounted and the long time are required to accomplish a small-sized and high-density LED lamp.

In the case of a multi-color LED lamp, LED chips are fixed to mounted electrodes by a conductive paste such as a silver paste, bonded to gold wires and sealed with a resin to be mounted. However, as the mounting area becomes smaller, the requirements for a mounting device employing the conventional system are becoming extremely strict and the development of this mounting device is expected to be difficult.

### SUMMARY OF THE INVENTION

The inventors of the present invention have conducted intensive studies on use of a resin-impregnated composite ceramic board which can be processed relatively easily and has high heat conductivity in order to simplify the mechanical processing step and have found that a bonding method is employed in place of the conventional counterboring method. Further, for the development of a multi-layer printed wiring board having extremely narrow LED chip mounting portions, they have conducted intensive studies on a method of manufacturing the board which can eliminate restricting conditions as much as possible so as to manufacture LED lamps from a broad viewpoint and have accomplished the present invention.

That is, according to the present invention, there is provided an LED lamp manufacturing process comprising manufacturing a multi-layer printed wiring board having a large number of LED lamp portions, each comprising a depressed portion whose side wall reflects light and has a mounted LED chip sealing resin container function and whose inner bottom has an LED chip mounting pattern, and a terminal pattern which is made conductive with the LED chip mounting pattern and formed on the outer under surface or outer side surface of the depressed portion, mounting predetermined LED chips on the LED chip mounting patterns, sealing the depressed portions with a resin and cutting the board into individual LED lamps, wherein the process comprises:

a) preparing a plated through hole printed wiring board (P) having LED chip mounting patterns and terminal patterns formed thereon;

b) preparing a through hole formed board (H) having through holes which correspond to the depressed portions and if necessary, have a treated wall to increase reflectance; and

c) aligning the through hole formed board (H) with the above plated through hole printed wiring board (P) and bonding them together.

### DETAILED DESCRIPTION OF THE PREFERRED EMBODIMENT

The LED lamp manufacturing process of the present invention will be described in detail hereinunder.

In the above through hole formed board (H), the “through hole” may be referred to as “window” and the wall of the through hole may be referred to as “wall”.

In the LED lamp manufacturing process of the present invention, a plated through hole printed wiring board (P) having a heat conductivity of 30 W(mk)⁻¹ or more is preferably used, and a double-side copper-clad resin-impregnated composite ceramic board is particularly preferred.

The above plated through hole printed wiring board (P) and the above through hole formed board (H) are preferably bonded together with a thermoplastic polyimide resin as an adhesive.

The manufacturing process according to a preferred embodiment of the present invention is an LED lamp manufacturing process comprising the steps of:

mounting LED chips on the LED mounting patterns of the plated through hole printed wiring board (P);

aligning the through hole formed board (H) with the above plated through hole printed wiring board (P);

bonding them together with an adhesive;

sealing the depressed portions of the assembly with a resin; and

cutting the assembly.

In this manufacturing process, a through hole formed board (H) having a short diameter of the through hole (window) of 0.8 mm or less, or even 0.3 mm which is assumed as the lower limit, can be advantageously used. Further, some or all of the reference mark portions of the LED chip mounting patterns formed on the plated through hole printed wiring board (P) overlap with the bonding portions (bottom wall) of the through hole formed board (H).

The constitution of the LED lamp of the present invention will be described hereinbelow.

The type (material, shape, capacity, caloric value, etc.) and number of the LED chips to be mounted are suitably selected, and the optimum structure is selected and designed according to the selected LED chips for the LED lamp to be manufactured by the process of the present invention.

The plated through hole printed wiring board (P) used to mount the LED chips is preferably made of a material having a heat conductivity of 30 W(mK)⁻¹ or more and has excellent machinability. Therefore, a double-side copper-clad resin-impregnated composite ceramic board is preferred, and a ceramic board made of an aluminum nitride-boron nitride-based continuous porous sintered material is particularly preferred. Examples of the double-side copper-clad resin-impregnated ceramic board and the resin-impregnated composite ceramic board include Cerazin (trade name; manufactured by Mitsubishi Gas Chemical Co., Inc.).

This resin-impregnated composite ceramic board and its manufacturing method are disclosed by U.S. Pat. No. 5,686,172.

To manufacture the plated through hole printed wiring board (P) from the double-side copper-clad resin-impregnated composite ceramic board, an LED chip mounting pattern is made conductive with a terminal pattern by filling a plated through hole formed in an LED chip mounting pattern portion to be sealed with a resin in the commonly used method of manufacturing a plated through hole printed wiring board. When the LED chip mounting pattern is made conductive with the terminal pattern by using a plated through hole formed in the outer side wall of an LED lamp, the plated through hole printed wiring board (P) must be designed in consideration of dimensional accuracy to prevent a leak of a resin used for sealing.

Preferably, when a through hole formed board (H) having a window short diameter of 0.8 mm or less, specifically 0.3 mm which is assumed as the lower limit, is used, after LED chips are mounted on the plated through hole printed wiring board (P), the through hole formed board (H) is assembled with the plated through hole printed wiring board (P) to manufacture LED lamps. In this case, some or all of the reference mark portions of each LED chip mounting pattern formed on the plated through hole printed wiring board (P) preferably overlap with the bonding portions (bottom) of the through hole formed board (H), and a printed wiring pattern which ensures this should be formed.

Especially the latter requirement, “some or all of the reference mark portions of each LED chip mounting pattern formed on the plated through hole printed wiring board (P) preferably overlap with the bonding portions (bottom) of the through hole formed board (H)”, can read that only an LED chip mounting pattern may be formed in each window portion, which greatly relaxes the conditions for the design of the printed wiring pattern and facilitates the manufacture of LED lamps.

The plated through hole printed wiring board (P) is manufactured by the above method.

In the method of manufacturing the plated through hole printed wiring board from an ordinary double-side copper-clad laminate board, when the LED chip mounting pattern is made conductive with the terminal pattern by using a plated through hole formed in an LED chip mounting pattern to be sealed with a resin, the plated through hole is filled. When the LED chip mounting pattern is made conductive with the terminal pattern by using the above plated through hole or a plated through hole formed in a terminal portion formed on the outer side wall of the LED lamp, the plated through hole printed wiring board must be designed in consideration of dimensional accuracy to prevent a leak of a resin used for sealing.

The surface of the pattern is generally plated with gold. Silver is suitably used to enhance reflectance, and bright nickel, platinum or platinum-iridium may be used to obtain corrosion resistance.

To plate the surface of the pattern with gold, (1) after the through hole is formed, plated with copper and filled, the pattern is formed and plated with nickel and with gold, or (2) after the through hole is formed, plated with copper and filled, a negative resist pattern is formed, plated with nickel and with gold, and removed to form the pattern with the gold plated surface as a resist.

A through hole corresponding to the window of each LED chip mounting pattern to be sealed with a resin is formed in the through hole formed board (H) and if necessary, the wall of the through hole is treated to increase its reflectance of visible radiation. The through hole formed board (H) is preferably made of the same material as the above plated through hole printed wiring board (P). However, any material which satisfies the requirements for productivity and heat conductivity may be suitably used, and what is designed to fully ensure electric insulation properties from the LED chip mounting patterns and a molded article manufactured by punching a metal plate or metal foil when the surface treatment is carried out may be advantageously used as the through hole formed board (H).

A method of manufacturing the through hole formed board (H) from a resin-impregnated composite ceramic board will be described hereinbelow.

When portions corresponding to the four corners of each LED lamp which are formed by cutting the resin-impregnated composite ceramic board and can be soldered as fixing portions to be mounted are necessary, they are first formed. In general, holes for forming the four corners of each LED lamp by cutting are formed in predetermined portions and the inner walls of the holes are electroless plated with copper, plated with nickel and then plated with gold. The gold plated holes are divided into four sections when the board is divided into LED lamps and form the four corners of each LED lamp.

A through hole corresponding to the window of each LED chip mounting pattern to be sealed with a resin is also formed. The through hole can be generally formed with a router. To improve productivity for mass-production, a punching method (in which a double-side rolled copper-clad board is manufactured and punched) or sandblast method, if the inclination of the wall of each through hole is permitted, is preferably used.

The reflectance of each LED lamp if necessary, can be increased by plating the inner wall of the above formed window (through hole) with a reflective metal such as bright nickel or by forming a heat resistant and light resistant resin film containing a white inorganic filler.

When a board having four corner fixing portions for each LED lamp is used in the above treatment for increasing reflectance, a protective film, et al is preferably formed on the fixing portions to carry out the process of the present invention. Alternatively, the above four corner fixing portions and window (through hole) for each LED lamp are formed in a resin-impregnated composite ceramic board (double-side rolled copper-clad board), the board is electroless plated with copper, a resist pattern is formed and plated with nickel to form a resist on a portion for forming a reflective film of the wall of the window, and the four-corner fixing portion pattern is plated with gold.

In the present invention, the plated through hole printed wiring board (P) and the through hole formed board (H) manufactured as described above are bonded together by the following first or second method to manufacture LED lamps.

First Method:

The plated through hole printed wiring board (P) and the through hole formed board (H) are aligned with each other and bonded together to manufacture a package for mounting LED chips.

Second Method:

LED chips are mounted on the plated through hole printed wiring board (P) and then the through hole formed board (H) manufactured above is aligned with and bonded to the above board (P).

The size of the package used in these methods is an LED chip mounting size for mounting a large number of LED lamp units.

Bonding between the plated through hole printed wiring board (P) and the through hole formed board (H) will be described hereinbelow.

Any adhesive having heat resistance and light resistance which can stand use conditions may be used as the adhesive. Examples of the adhesive include polyester-based, acryl-based, epoxy-based and silicone-based adhesives and solutions of a thermoplastic resin or a mixture of thermoplastic resins such as polyesters, polyether imides, polycarbonates, polyphenylene ethers, polyester imides and polyimides. Out of these, adhesives which do not ooze out, that is, adhesives which contain a resin having a high molecular weight as an adhesive component are preferred. In the case of a resin solution, a resin as a solute having a high melting point is preferably selected and thermoplastic polyimide resins are particularly preferred, as exemplified by Upitite UPA-N111 and N221 (trade name; manufactured by Ube Industries, Ltd.) and Rikacoat EN20 (trade name; manufactured by Shin Nippon Rika Co., Ltd.).

A thermoplastic polyimide resin can be used to bond different types of materials because its layer serves to ease stress caused by a difference in thermal expansion coefficient between them.

It is preferred to form an adhesive layer on both of the above boards and also preferred to form a primer layer for promoting adhesion between them.

To form an adhesive layer or primer layer on the plated through hole printed wiring board (P), screen printing or photoresist method is preferably used. To form the above layer on the through hole formed board (H), an adhesive layer is preferably formed on the bonding surface by printing, stamping or dipping. When the through hole formed board (H) is not made of an insulating material, highly-reliable electric insulation from the plated through hole printed wiring board (P) is required. In this case, preferably, the adhesive layer formed on the above plated through hole printed wiring board (P) is used to secure highly reliable insulation, or an electrically insulating strong adhesive layer having high adhesion is formed on the bonding surface of the through hole formed board (H).

The plated through hole printed wiring board (P) and the through hole formed board (H) are generally bonded together by heating under pressure.

The plated through hole printed wiring board (P) is placed on a press auxiliary board such as an aluminum board or resin-impregnated ceramic board in such a manner that the LED chip mounting surface faces up, the plated through hole formed board (H) is placed on and aligned with the plated through hole printed wiring board (P) under a microscope and preliminarily fixed on the board (P), a press auxiliary board is placed on the through hole formed board (H), and the resulting assembly is inserted between press hot plates through heat resistant cushions to bond them together by heating under reduced pressure. When a thermoplastic polyimide resin is used as an adhesive, dislocation at the time of heating under pressure is relatively small. However, when a thermosetting resin having high fluidity is used, close attention must be paid to prevent dislocation at the time of heating under pressure.

A description is subsequently given of the mounting of LED chips.

In the above first method, predetermined LED chips are mounted in the mounting portion of the bottom of each hole of a package for mounting LED chips, which has a large number of LED lamp units and is manufactured by bonding.

When the above second method is preferred and a smaller package for mounting LED chips is used, predetermined LED chips are mounted on the plated through hole printed wiring board (P), the through hole formed board (H) having an adhesive layer is placed on the plated through hole printed wiring board (P), aligned with the board (P) under a microscope and preliminarily fixed to the board (P), a press auxiliary board is placed on the through hole formed board (H), and the resulting assembly is inserted into press hot plates through heat resistant cushions to bond them together by heating under pressure.

Supersonic bonding can be suitably used to mount LED chips.

After the bonding work, the obtained assembly is sealed with a resin, suitably tested and divided into individual LED lamps.

When a double-side copper-clad resin-impregnated composite ceramic board or resin-impregnated composite ceramic board is selected as a preferred embodiment of the present invention, the obtained assembly can be advantageously divided into LED lamps with a dicing saw.

In the above second method, since the through hole formed board (H) is not existent when LED chips are mounted, the conventional method may be used as it is.

That is, the space corresponding to portions (bottom) other than the windows (through hole) of the through hole formed board (H) serves as the margin of mounting. This value is about 800 μm to 1,000 nm ((100 μm to 150 μm)×4+200×2) when the wall thickness is 100 μm to 150 μm and the cutting margin for the dicing saw is 200 μm. This means that even when the short diameter of each window (through hole) of the through hole formed board (H) is 0.3 mm, the width of the mounting space is 1.1 mm to 1.3 mm. This second method makes it easy to mount LED chips as compared with the first method, and the manufacture of a small-sized product is possible.

In this manufacturing method, since LED chips have been mounted, it is necessary to select an adhesive resin which can be used in the subsequent step of sealing with a transparent resin and the step of mounting the completed LED lamps and can bond together the above boards substantially without the deterioration of the mounted LED chips.

For example, a thermosetting resin containing a monomer causes contamination by a resin flow or the deposition of its vapor and cannot be generally used. In the process of the present invention, however, use of the above thermosetting resin rarely causes a problem when it does not cause contamination by evaporation. Accordingly, a thermosetting resin composition containing a white pigment may be used in both a reflective layer and an adhesive layer.

Bonding with a thermoplastic resin does not cause the contamination of holes which become the four corner fixing portions of each LED lamp because the resin does not ooze out, does not require curing time and can be modified. Further, as the adhesive layer functions as a layer for easing stress caused by a difference in thermal expansion coefficient between the two boards, it can be advantageously used to bond different types of materials.

As described above, the manufacturing process of the present invention is to manufacture the plated through hole printed wiring board (P) and the through hole formed board (H) separately and bond them together. Accordingly, the materials of these boards may be different and manufactured by different production methods.

For example, the plated through hole printed wiring ceramic board (P) is manufactured by a green sheet method which enables V-shaped grooves to be formed between LED lamp units. Meanwhile, the through hole formed board (H) is manufactured by punching a metal sheet to remove a surface opposite to the bonding surface so that the board can be divided into individual LED lamp units. Thereafter, the above boards are bonded together, LED chips are mounted, and then the resulting assembly is divided into individual LED lamp units.

When the through hole formed board (H) is manufactured by punching a metal sheet, the reflective surface is made in silver tone (aluminum surface, nickel surface or silver plated surface), and when the four corners can be soldered, desired physical properties are preferably provided by a one-sided treatment. After only one side is subjected to a desired treatment (nickel or silver plating or plating with copper, gold, etc.) by compression molding as a product having desired irregularities, through holes corresponding to LED chip mounting portions are formed by punching. These methods may be selected as required.

### EXAMPLES

The following examples are given to further illustrate the present invention.

### Example 1

A multi-color LED lamp unit board for mounting 3 LED chips was manufactured in this Example 1. Each LED lamp unit had a width of 1.1 mm, a height of about 1 mm and a length of about 3.6 mm, a through hole having a diameter of 0.8 mm was formed at the four corners of the LED lamp unit as portions for mounting to an external substrate, and an LED chip mounting pattern was formed on the bottom of a depressed portion having a depth of about 0.5 mm, a width of 0.8 mm and a length of about 3.2 mm and made conductive with a terminal pattern formed on the rear surface by a through hole having a diameter of 0.1 mm.

LED lamp units were arranged in a matrix of 7 columns and 20 rows with a cutting margin of about 0.2 mm.

A double-side copper-clad resin-impregnated composite ceramic board (Cerazin CCL-ANB21) manufactured by cladding an aluminum nitride-boron nitride sintered material impregnated with a cyanate-epoxy resin to a thickness of 0.5 mm (h-BN of 20%, porosity of 21 volt) with a 12 μm-thick low-profile rolled electrodeposited copper foil was used. This ceramic board had a thermal conductivity of about 71 W (mK)⁻¹.

0.1 mm-diameter through holes were formed in this ceramic board with a diamond coated drill and plated. 0.8 mm-diameter holes corresponding to the four corner portions of each LED lamp unit were formed and plated with nickel and gold to obtain a plated through hole printed wiring board.

The same double-side copper-clad resin-impregnated composite ceramic board (Cerazin CCL-ANB21) as above was used to manufacture a through hole formed board. 0.8 mm-diameter holes corresponding to the four corner portions of each LED lamp unit were formed and plated, one side of the board was covered with a resist and the other side was plated with nickel and gold without a 0.15 mm wide pattern around the holes, the resist was removed, and the board was etched with gold as a resist film to obtain a board having no metal foil on one side and a pattern around each hole on the other side.

Through holes having a width of 0.8 mm and a length of about 3.2 mm were formed in this board with a router. The dislocation of the start position by the shaking of the router was suppressed by a method in which the through holes were formed with the router after predetermined through holes were formed at router processing start positions with a diamond coated drill.

The plated through hole printed wired board and the through hole formed board manufactured above were machined. Then, they were bonded together with thermoplastic polyimide resin varnish (trade name: Upitite N221 of Ube Industries, Ltd.) as an adhesive.

An adhesive layer was formed on the plated through hole printed wiring board as a pattern more slender than the bonding portions and dried. The above adhesive was applied to the entire bonding surface of the through hole formed board and dried with the bonding surface facing down. When excess portions and shortage portions of the adhesive were visually observed, there was no problem.

The above plated through hole printed wiring board having an adhesive layer was placed on a resin-impregnated composite ceramic press auxiliary board in such a manner that the LED chip mounting surface faced up, the through hole formed board having an adhesive layer was placed on the plated through hole printed wiring board, aligned with the board under a magnifying glass and temporarily fixed to the board, a press auxiliary board was placed on the through hole formed board, the resulting assembly was inserted between press hot plates heated at 230° C. through heat resistant cushions, the upper hot plate was slowly lowered, and the assembly was maintained at a pressure of 3 MPa for 15 minutes and then heated at a hot plate temperature of 150° C. for 30 minutes and taken out from the plates to complete bonding.

When the obtained bonded product was cut by a dicing saw without mounting LED chips and sealing with a resin, it was cut well.

### Example 2

A multi-color LED lamp unit board for mounting 5 LED chips was manufactured in this Example 2.

The LED lamp unit had a width of about 0.8 mm, a height of about 0.8 mm and a length of about 5.0 mm, a through hole having a diameter of 0.7 mm was formed at the four corners of the LED lamp unit as portions for mounting to an external substrate, and an LED chip mounting pattern was formed on the bottom of a depressed portion having a side wall thickness of 0.15 mm, a depth of about 0.4 mm, a width of 0.5 mm and a length of about 4.4 mm and made conductive with a terminal pattern formed on the rear surface by a through hole having a diameter of 0.12 mm.

LED lamp units were arranged in a matrix of 6 columns and 20 rows with a cutting margin of about 0.2 mm.

A double-side copper-clad rein-impregnated composite ceramic board (Cerazin CCL-ANB21) manufactured by cladding an aluminumnitride-boron nitride sintered material impregnated with a cyanate-epoxy resin to a thickness of 0.4 mm (h-BN of 20%, porosity of 21 vol %) with a 12 μm-thick low-profile rolled electrodeposited copper foil was used.

0.12 mm-diameter through holes were formed in this ceramic board with a diamond coated drill and plated. Thereafter, 0.7 mm-diameter through holes corresponding to the four corner portions of each LED lamp unit were formed and plated. A resist pattern was then formed and a predetermined pattern was formed by etching and electroplated with nickel and gold to obtain a through hole printed wiring board. Location marks for mounting LED chips to the plated through hole printed wiring board were existent under the wall including cut portions, and copper end faces were exposed only to the cut surfaces when the assembly was divided into individual LED lamps.

A through hole formed board was manufactured from the same double-side copper-clad resin-impregnated composite ceramic board (Cerazin CCL-ANB21) as above. 0.7 mm-diameter through holes corresponding to the four corner portions of each LED lamp unit were formed and plated, the entire surface of one side was covered with a resist, the other side was plated with nickel and gold without a 0.15 mm wide pattern around each hole, the resist was removed, and the board was etched with gold as the resist film to obtain a board having no metal foil on one side and a pattern around each hole on the other side.

Thereafter, through holes having a width of 0.5 mm and a length of about 4.4 mm were formed in this board. Since through holes were not well formed with a router, a large number of holes having a distance between centers of 3.9 mm were formed by a diamond coated drill having a diameter of 0.5 mm to form through holes.

The plated through hole printed wiring board and the plated through hole formed board manufactured above were machined. The obtained boards were placed one upon the other and it was confirmed from the positional relationship between the two that they could be bonded together.

A resin-impregnated composite ceramic board having a width of about 0.3 mm, a length of about 4.0 mm and a height of about 0.2 mm was positioned in each LED chip mounting portion of the through hole printed wiring board as an LED chip dummy and bonded to the printed wiring board.

A solution of a thermoplastic polyimide resin which is curable at a low temperature prepared by adding 5% of N-methylpyrrolidone (trade name: Upitite UPA-N-221 of Ube Industries, Ltd.) was used as an adhesive solution to bond them together.

The above adhesive was applied to the entire bonding surface of the through hole formed board, dried with air with the coated surface facing down, and heated at 100° C. or less to be dried. When excess portions and shortage portions of the adhesive were visually observed, there was no problem.

The above plated through hole printed wiring board having the above LED chip dummy was placed on a resin-impregnated composite ceramic press auxiliary board in such a manner that the LED chip mounting surface faced up, the through hole formed board having an adhesive layer was placed on the above plated through hole printed wiring board after temporary alignment by means of reference pins, aligned with the board under a microscope and temporarily fixed to the board, a press auxiliary board was placed on the through hole formed board, the resulting assembly was inserted between press hot plates heated at 200° C. through cushions, the upper hot plate was slowly lowered, the pressure was maintained at 3 MPa for 5 minutes, the hot plates were cooled to 175° C. and maintained at a reduced pressure of about 1.3 Mpa or less for 60 minutes, and the resulting assembly was taken out to complete bonding.

In the temporary alignment by means of the guide pins, inconvenience caused by a collision between the LED chip dummy and the through hole formed board having an adhesive layer did not occur.

When the above obtained bonded product was cut by a dicing saw without sealing with a resin, it was cut well.

Effect of the Invention

According to the manufacturing process of the present invention, the plated through hole printed wiring board (P) and the through hole formed board (H) are manufactured separately and bonded together. The manufacture of LED lamps which is difficult after the above boards are bonded together becomes easy after they are manufactured separately, and they are manufactured from optimum materials by optimum methods and can be bonded together. In the present invention, after LED chips are mounted on the plated through hole printed wiring board (P), the plated through hole printed wiring board (P) is bonded to the through hole formed board (H). Therefore, the manufacture range of a printed wiring pattern for mounting LED chips is expanded, and assembly work becomes possible with a greatly increased LED chip mounting space, which is greatly significant from an industrial point of view.

What is claimed is:

1. An LED lamp manufacturing process comprising manufacturing a multi-layer printed wiring board having a large number of LED lamp portions, each comprising a depressed portion whose side wall reflects light and has a mounted LED chip sealing resin container function and whose inner bottom has an LED chip mounting pattern, and a terminal pattern which is made conductive with the LED chip mounting pattern and formed on the outer under surface or outer side surface of the depressed portion, mounting predetermined LED chips on the LED chip mounting patterns, sealing the depressed portions with a resin and cutting the board into individual LED lamps, wherein the process comprises:
a) preparing a plated through hole printed wiring board (P) having LED chip mounting patterns and terminal patterns formed thereon;
b) preparing a through hole formed board (H) having through holes which correspond to the depressed portions and if necessary, have a treated wall to increase reflectance; and
c) aligning the through hole formed board (H) with the above plated through hole printed wiring board (P) and bonding them together.

2. The LED lamp manufacturing process according to claim 1, wherein the plated through hole printed wiring board (P) has a heat conductivity of 30 W(mk)⁻¹ or more.

3. The LED lamp manufacturing process according to claim 1, wherein the plated through hole printed wring board (P) is formed from a double-side copper-clad resin-impregnated composite ceramic board.

4. The LED lamp manufacturing process according to claim 1, wherein bonding is carried out with a thermoplastic polyimide resin.

5. The LED lamp manufacturing process according to claim 1, wherein LED chips are mounted on each LED mounting pattern of the plated through hole printed wiring board (P), the through hole formed board (H) is aligned with and bonded to the plated through hole printed wiring board (P), the depressed portions are sealed with a resin, and the assembly is cut.

6. The LED lamp manufacturing process according to claim 1, wherein the short diameter of the through holes of the through hole formed board (H) is 0.8 mm or less.

7. The LED lamp manufacturing process according to claim 5, wherein some or all of the location marks of the LED chip mounting patterns formed on the plated through hole printed wiring board (P) overlap with the bonding portions of the through hole formed board (H).
